(19) United States
(12) Patent Application Publication
(10) Pub. No.: US 2007/0085576 A1
(43) Pub. Date: Apr. 19, 2007

(54) Output driver circuit with multiple gate devices

(76) Inventor: Hector Sanchez, Cedar Park, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/251,470

(22) Filed: Oct. 14, 2005

(51) Int. Cl. H03B 1/00

(52) U.S. Cl. 327/112

(57) ABSTRACT

An output driver circuit comprising a plurality of multiple gate field effect transistors (MGFETs) that provides an output signal is provided. Each output driver circuit may have a first MGFET gate for receiving a drive signal, a second MGFET gate for biasing purposes, and a current electrode for providing an output signal. Some embodiments provide a drive signal and a bias signal to the same MGFET device. Alternate embodiments provide the same drive signal (or alternately the same bias signal) to both gates of the same MGFET device. Some embodiments may provide an output driver circuit having variable output impedance. Predriver circuitry and/or bias control circuitry may optionally be used.

### RELATED APPLICATIONS

A related, copending application is entitled “Method and Circuit for Multiplying Signals With a Transistor Having More Then One independent Gate Structure”, by Yang Du et al., application Ser. No. 10/728,621, assigned to Freescale Semiconductor, and was filed on Dec. 5, 2003.

A related, copending application is entitled “Fully Programmable Phase Locked Loop”, by Hector Sanchez et al., application Ser. No. 11/069,664, assigned to Freescale Semiconductor, Inc., and was filed on Mar. 1, 2005.

A related application is entitled “Signal Converters With Multiple Gate Devices” by Mohamed Moosa et al., application number attorney docket number SC14312TP, assigned to Freescale Semiconductor, Inc. and filed simultaneously herewith.

A related application is entitled “Voltage Controlled Oscillator Having Digitally Controlled Phase Adjustment And Method Therefor” by Hector Sanchez et al., application number attorney docket number SC14387TC, assigned to Freescale Semiconductor, Inc. and filed simultaneously herewith.

A related application is entitled “Voltage Controlled Oscillator With a Multiple Gate Transistor And Method Therefor” by Kalpat et al., application number attorney docket number SC14354TP, assigned to Freescale Semiconductor, Inc. and filed simultaneously herewith.

### FIELD OF THE INVENTION

The present invention relates generally to an output driver circuit, and more particularly to an output driver circuit with multiple gate devices.

### RELATED ART

Output driver circuits are used in a wide variety of integrated circuit (IC) applications. For example, output driver circuits may be used to drive signals external to an integrated circuit. Such an output driver is often required to have predetermined electrical characteristics that may vary depending upon the application in which the IC is used. Furthermore, the electrical characteristics of the output driver circuit may itself vary due to a variety of causes, including manufacturing (e.g. process parameters) and environmental (e.g. temperature, voltage) factors. It is thus useful to provide an output driver circuit that can meet a variety of predetermined electrical characteristics in spite of variations due to other factors (e.g. manufacturing and environmental).

### BRIEF DESCRIPTION OF THE DRAWINGS

The present invention is illustrated by way of example and not limited by the accompanying figures, in which like references indicate similar elements, and in which:

FIG. 1 illustrates an exemplary output driver circuit having multiple gate devices, consistent with one embodiment of the invention;

FIG. 2 illustrates an exemplary output driver circuit having multiple gate devices, consistent with an alternate embodiment of the invention;

FIG. 3 illustrates an exemplary output driver circuit having multiple gate devices, consistent with an alternate embodiment of the invention;

FIG. 4 illustrates an exemplary output driver circuit having multiple gate devices, consistent with an alternate embodiment of the invention;

FIG. 5 illustrates an exemplary output driver circuit having multiple gate devices, consistent with an alternate embodiment of the invention; and

FIG. 6 illustrates an exemplary multiple gate field effect transistor (MGFET), consistent with one embodiment of the invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

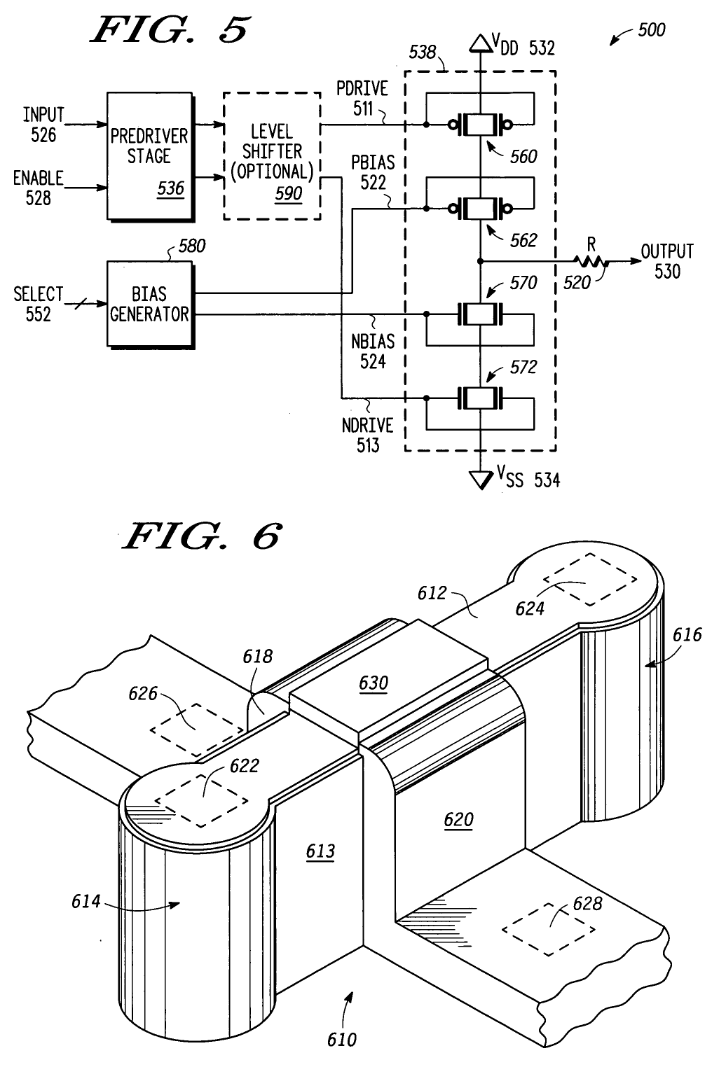

As described herein, a multiple gate field effect transistor (MGFET) is defined to be a transistor having two or more gate electrodes with a common channel for conducting current between a first current electrode and a second current electrode. Note that the voltage applied to each gate electrode will modulate the conductivity of the common channel. Note that the voltage applied to each gate electrode may be the same or may be different. If the voltage applied to each gate electrode may be different, the multiple gates are considered to be electrically independent. Note that if the voltage applied to each gate electrode is approximately the same, the MGFET may be implemented as a FINFET (i.e. a field effect transistor using a fin-shaped channel region structure; see FIG. 6 for one example of a FINFET).

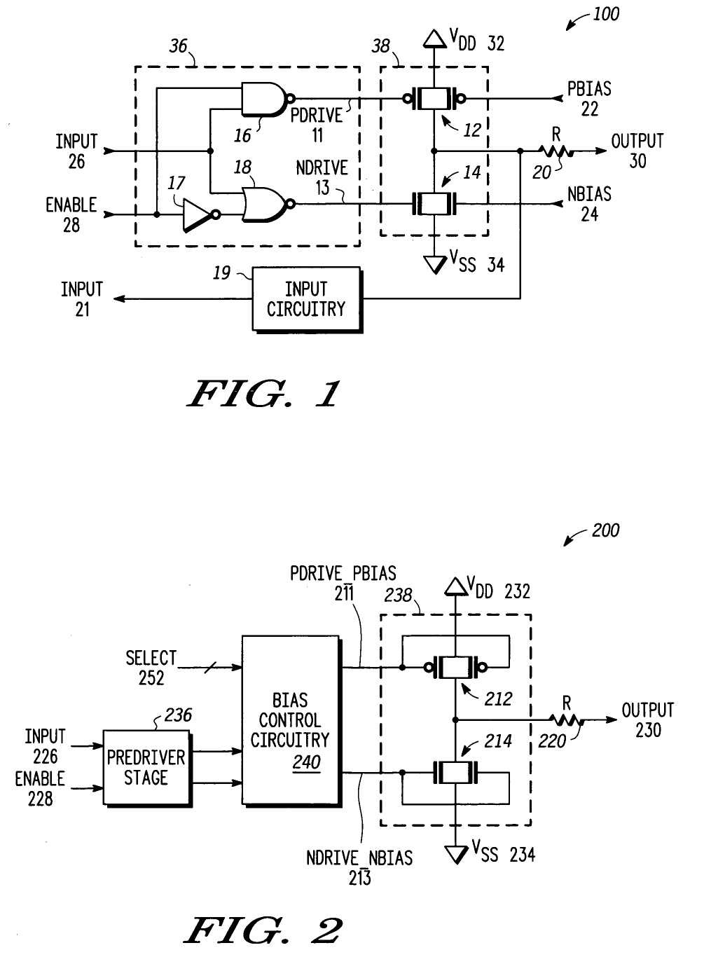

FIG. 1 illustrates, in partial block and partial schematic diagram form, an exemplary output driver circuit 100 having a plurality of multiple gate field effect transistor (FET) devices 12, 14 in accordance with one embodiment of the present invention. In the illustrated example, a predriver stage or circuit 36 is coupled to an output stage 38. In one embodiment, predriver 36 has a NAND gate 16 which receives enable 28 as a first input and which receives input 26 as a second input. The output of NAND gate 16, labeled pdrive signal 11, is coupled to a first control electrode or gate of p-channel MGFET 12. The enable 28 signal is also provided to the input of inverter 17. The output of inverter 17 is coupled to a second input of NOR gate 18. The first input of NOR gate 18 is coupled to input signal 26. The output of NOR gate 18, labeled ndrive signal 13, is coupled to a first control electrode or gate of n-channel MGFET 14. The second control electrode or gate of MGFET 12 is coupled to receive a pbias signal 22, and the second control electrode or gate of MGFET 14 is coupled to receive an nbias signal 24. A first current electrode of MGFET 12 is coupled to a first power supply voltage 32 (e.g. power or VDD), and a second current electrode of MGFET 12 is coupled to a first terminal of a resistive element 20. A first current electrode of MGFET 14 is coupled to the first terminal of resistive element 20, and a second current electrode of MGFET 14 is coupled to a second power supply voltage 34 (e.g. approximately ground or VSS). A second terminal of resistive element 20 provides an output signal 30. Alternate embodiments may not use resistive element 20. Yet other embodiments may use any type of circuitry between the common current electrodes of MGFETs 12, 14 and the output signal 30.

In one embodiment, output signal 30 is provided external to the integrated circuit on which output driver circuit 100 is formed. This external provision of output signal 30 may be performed in any desired manner, including, for example, any type of integrated circuit terminal such as a pad, bump, and or pin. In the illustrated embodiment, the circuit 100 is an input/output buffer which also has an input path from the integrated circuit terminal. In one embodiment, the input path is via output 30, optionally via resistive element 20, optionally via input circuitry 19, and is provided as input signal 21. In alternate embodiments, circuit 100 is an output buffer only and the input path to signal input 21 is not required. In one embodiment, input circuitry 19 may have a latch for storing the input value. In alternate embodiments, the input circuitry 19 may have any desired circuitry. In alternate embodiments of circuit 100, predriver circuit 36 may not be present, or may have different circuitry. The pbias signal 22 and the nbias signal 24 may be provided by any appropriate circuitry to bias MGFET 12 and MGFET 14 in a desired manner as described below.

Operation of the circuit 100 of FIG. 1 will now be described. In FIG. 1, output stage 38 receives pdrive 11 as the drive input to p-channel MGFET 12, and receives ndrive 13 as the drive input to n-channel MGFET 14. Note that the pdrive signal 11 may be used to drive device 12. The pdrive signal 11 may be used to determine the conductivity of device 12 (i.e. transition device 12 from non-conducting to conducting, or from conducting to non-conducting). Note that the ndrive signal 13 may be used to drive device 14. Thus, the ndrive signal 13 may be used to determine the conductivity of device 14 (i.e. transition device 14 from non-conducting to conducting, or from conducting to non-conducting).

When it is desired for output 30 to switch from approximately VSS 34 to VDD 32, signal pdrive 11 is driven from VDD 32 to VSS 34, and signal ndrive 13 is also driven from VDD 32 to VSS 34. This causes output 30 to start switching from VSS 34 to VDD 32. During this switching, the output impedance of circuit 100 (as seen at output 30) is dependent on the voltage difference between VDD 32 and pdrive 11 as well as the voltage difference between VDD 32 and pbias 22. Note that since n-channel MGFET 14 is substantially non-conducting, n-channel MGFET 14 has little impact on the output impedance of circuit 100. In this case, the output impedance of output stage 38, and thus the output impedance of circuit 100, is determined by both pdrive 11 and pbias 22. Since the voltage of pdrive 11 is constrained by the voltage desired at output 30, the pbias signal 22 may be used as the primary control to determine the impedance of output stage 38, and thus the output impedance of circuit 100.

When it is desired for output 30 to switch from approximately VDD 32 to VSS 34, signal pdrive 11 is driven from VSS 34 to VDD 32, and signal ndrive 13 is also driven from VSS 34 to VDD 32. This causes output 30 to start switching from VDD 32 to VSS 34. During this switching, the output impedance of circuit 100 (as seen at output 30) is dependent on the voltage difference between VSS 34 and ndrive 13 as well as the voltage difference between VSS 34 and nbias 24. Note that since p-channel MGFET 12 is substantially non-conducting, p-channel MGFET 12 has little impact on the output impedance of circuit 100. In this case, the output impedance of output stage 38, and thus the output impedance of circuit 100, is determined by both ndrive 13 and nbias 24. Since the voltage of ndrive 13 is constrained by the voltage desired at output 30, the nbias signal 24 may be used as the primary control to determine the impedance of output stage 38, and thus the output impedance of circuit 100.

In FIG. 1, a resistive element (R) 20 is optionally added to output driver circuit 100. Alternate embodiments may not use resistive element 20. Resistive element 20 may be used for electrostatic discharge protection purposes, and/or to aid in linearization (over VDD 32 variation) of the output impedance of output driver circuit 100.

Predriver stage 36 may be used to provide the drive signals, pdrive 11 and ndrive 13, to devices 12 and 14, respectively. The predriver stage 36 illustrated in FIG. 1 selectively provides the input signal 26 to the drive inputs of devices 12 and 14 based upon the value of enable signal 28. Alternate embodiments may use any desired predriver circuit (e.g. 36), or may use no predriver circuit. For example, if output driver circuit 100 was intended to operate only as an output, and not as an input, there would be no need for predriver 36 to tri-state circuit 38. Predriver 36 tri-states circuit 38 by driving pdrive 11 to VDD 32 and ndrive 13 signals to VSS 34 so that both devices 12 and 14 are non-conducting. Thus, output 30 will be high impedance.

If output driver 100 is capable of receiving an input from output node 30, then the input circuitry 19 is used to pass the input signal received at output node 30 to input path 21. Note that enable 28 must be approximately VSS 34 so that devices 12 and 14 are non-conducting (i.e. are off and high impedance).

Thus, the voltage applied to pbias signal 22 and nbias signal 24 may be varied in order to provide an output driver stage 38, and thus an output driver circuit 100 having variable impedance. Note that in an alternate embodiment, pbias 22 and pdrive 11 may be electrically coupled to a same voltage; similarly nbias 24 and ndrive 13 may be electrically coupled to a same voltage. However, electrically coupling the drive and bias signals may limit the ability to variably control the output impedance of output driver stage 38.

In some embodiments, circuit 100 may use transistors 12, 14 which have multiple gates that are not independent. In alternate embodiment, circuit 100 may use transistors 12, 14 which have multiple gates that are independent.

FIG. 2 illustrates, in partial block and partial schematic diagram form, an exemplary output driver circuit 200 having a plurality of MGFET devices 212, 214 in accordance with an alternate embodiment of the present invention. In the illustrated example, a predriver stage or circuit 236 is coupled to an output stage 238 by way of bias control circuitry 240. In one embodiment, predriver 236 receives an enable signal 228 as a first input and receives an input signal 226 as a second input. In one embodiment, predriver 236 may be implemented in the same manner as predriver circuit 36 of FIG. 1. In alternate embodiments, predriver circuit 236 may be implemented using any desired circuitry. Bias control circuitry 240 receives at least one select signal 252 and one or more inputs from predriver stage 236. Bias control circuitry 240 then provides a pdrive_pbias signal to a first control electrode or gate of p-channel MGFET 212 and to a second control electrode or gate of MGFET 212. Bias control circuitry 240 also provides an ndrive_nbias signal to a first control electrode or gate of n-channel MGFET 214 and to a second control electrode or gate of MGFET 214. Thus two control electrodes of MGFET 212 are not independent of each other. Similarly, two control electrodes of MGFET 214 are not independent of each other.

A first current electrode of MGFET 212 is coupled to a first power supply voltage 232 (e.g. power or VDD), and a second current electrode of MGFET 212 is coupled to a first terminal of a resistive element 220. A first current electrode of MGFET 214 is coupled to the first terminal of resistive element 220, and a second current electrode of MGFET 214 is coupled to a second power supply voltage 234 (e.g. approximately ground or VSS). A second terminal of resistive element 220 provides an output signal 230. Alternate embodiments may not use resistive element 220. Yet other embodiments may use any type of circuitry between the common current electrodes of MGFETs 212, 214 and the output signal 230.

In one embodiment, output signal 230 is provided external to the integrated circuit on which output driver circuit 200 is formed. This external provision of output signal 230 may be performed in any desired manner, including, for example, any type of integrated circuit terminal such as a pad, bump, and or pin. In the illustrated embodiment, the circuit 200 is an output buffer only with no input capability. However, in alternate embodiments, circuit 200 may be implemented as an input/output buffer which also has an input path (not shown) from the integrated circuit terminal. In one embodiment, as illustrated in FIG. 1, the input path may be via output 230. In alternate embodiments of circuit 200, predriver circuit 236 may not be present, or may be implemented using any desired circuitry. The pdrive_pbias signal 211 and the ndrive_nbias signal 213 may be provided by any appropriate circuitry to both drive and bias MGFET 212 and MGFET 214 in a desired manner as described below.

Operation of the circuit 200 of FIG. 2 will now be described. One primary difference between circuit 200 of FIG. 2 and circuit 100 of FIG. 1 is that bias control circuitry 240 has been added to provide pdrive_pbias signal 211 and ndrive_nbias signal 213. Note that the pdrive_pbias signal 211 is provided to both gates of device 212 and thus acts as both a drive signal and as a bias signal to device 212. The bias control circuitry 240 thus modulates the voltage amplitude of the pdrive_pbias signal 211 in order to modulate the output impedance of output stage 238, and thus to modulate the output impedance of output driver 200. In one embodiment, one or more select signals 252 may be used by bias control circuitry 240 to select the voltage amplitude of the pdrive_pbias signal 211 to achieve a desired output impedance of output driver circuit 200 when output 230 is switching from approximately VSS 234 to VDD 232.

Similarly, the ndrive_nbias signal 213 is provided to both gates of device 214 and thus acts as both a drive signal and as a bias signal to device 214. The bias control circuitry 240 thus modulates the voltage amplitude of the ndrive_nbias signal 213 in order to modulate the output impedance of output stage 238, and thus to modulate the output impedance of output driver 200. In one embodiment, one or more select signals 252 may be used by bias control circuitry 240 to select the voltage amplitude of the ndrive_nbias signal 213 to achieve a desired output impedance of output driver circuit 200 when output 230 is switching from approximately VDD 232 to VSS 234.

Note that the bias control circuitry 240 provides the bias signals (e.g. 211, 213) to the MGFETS 212, 214, respectively, and thus determines the voltage levels of the bias signals. The voltage levels of the bias signals then affect whether the MGFETs 212, 214 are conducting or non-conducting. In addition the voltage levels of the bias signals also affect the output impedance of the output driver 200. Note that in alternate embodiments, the voltage level of one or more of the bias signals may not be variable.

Note that an alternate embodiment of bias control circuitry 240 may be used to provide separate drive and bias signals to the multiple gates of device 212, and may also be used to provide separate drive and bias signals to the multiple gates of device 214. The decoupling of the drive and bias signals of devices 212 and 214 may be advantageous for some embodiments of output driver circuit 200.

Note that predriver stage 236 may be implemented in a same manner as predriver stage 36 of FIG. 1. Alternate embodiments of circuit 200 may use any desired predriver stage 236, or may optionally have no predriver stage 236.

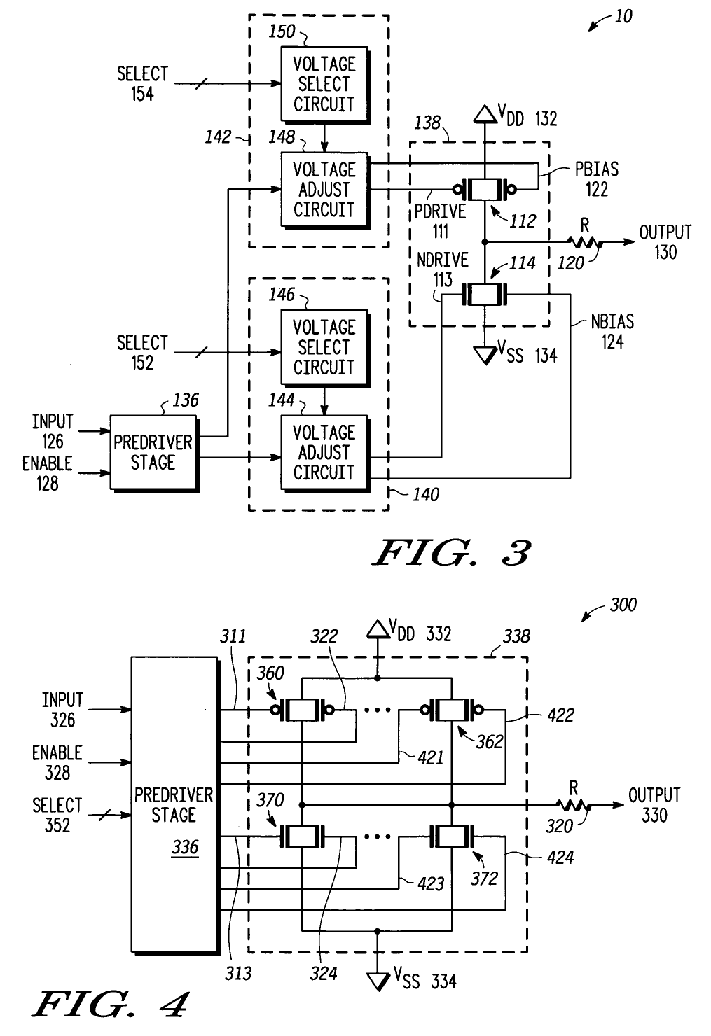

FIG. 3 illustrates, in partial block and partial schematic diagram form, an exemplary output driver circuit 10 having a plurality of MGFET devices 112, 114 in accordance with an alternate embodiment of the present invention. In the illustrated example, a predriver stage or circuit 136 is coupled to an output stage 138 by way of bias control circuitry 140 and 142. In one embodiment, predriver 136 receives an enable signal 128 as a first input and receives an input signal 126 as a second input. In one embodiment, predriver 236 may be implemented in the same manner as predriver circuit 36 of FIG. 1. In alternate embodiments, predriver circuit 136 may be implemented using any desired circuitry. Bias control circuitry 142 receives at least one select signal 154 and one or more inputs from predriver stage 136. Bias control circuitry 142 then provides a pdrive signal 111 to a first control electrode or gate of p-channel MGFET 112, and provides a pbias signal 122 to a second control electrode or gate of MGFET 112. Bias control circuitry 140 receives at least one select signal 152 and one or more inputs from predriver stage 136. Bias control circuitry 140 then provides an ndrive signal 113 to a first control electrode or gate of n-channel MGFET 114, and provides an nbias signal 124 to a second control electrode or gate of MGFET 114.

In the illustrated embodiment, bias control circuitry 142 has a voltage select circuit 150 that receives one or more select signals 154 and provides an input signal to a voltage adjust circuit 148. Voltage adjust circuit 148 also receives at least one signal from predriver stage 136. The voltage adjust circuit 148 then uses the input from the voltage select circuit 150 to selectively adjust the voltage coming in from the predriver stage 136 in order to provide the drive signal 111 (pdrive) and the bias signal 122 (pbias) to the p-channel MGFET 112 of output buffer 138. In the illustrated embodiment, bias control circuitry 140 has a voltage select circuit 146 that receives one or more select signals 152 and provides an input signal to a voltage adjust circuit 144. Voltage adjust circuit 144 also receives at least one signal from predriver stage 136. The voltage adjust circuit 144 then uses the input from the voltage select circuit 146 to selectively adjust the voltage coming in from the predriver stage 136 in order to provide the drive signal 113 (ndrive) and the bias signal 124 (nbias) to the n-channel MGFET 114 of output buffer 138. Note that the two control electrodes of MGFET 112 may be independent of each other since they receive different control signals. Similarly, the two control electrodes of MGFET 114 may be independent of each other since they receive different control signals.

A first current electrode of MGFET 112 is coupled to a first power supply voltage 132 (e.g. power or VDD), and a second current electrode of MGFET 112 is coupled to a first terminal of a resistive element 120. A first current electrode of MGFET 114 is coupled to the first terminal of resistive element 120, and a second current electrode of MGFET 114 is coupled to a second power supply voltage 134 (e.g. approximately ground or VSS). A second terminal of resistive element 120 provides an output signal 130. Alternate embodiments may not use resistive element 120. Yet other embodiments may use any type of circuitry between the common current electrodes of MGFETs 112, 114 and the output signal 130.

In one embodiment, output signal 130 is provided external to the integrated circuit on which output driver circuit 10 is formed. This external provision of output signal 130 may be performed in any desired manner, including, for example, any type of integrated circuit terminal such as a pad, bump, and or pin. In the illustrated embodiment, the circuit 10 is an output buffer only with no input capability. However, in alternate embodiments, circuit 10 may be implemented as an input/output buffer which also has an input path (not shown) from the integrated circuit terminal. In one embodiment, as illustrated in FIG. 1, the input path may be via output 130. In alternate embodiments of circuit 10, predriver circuit 136 may not be present, or may be implemented using any desired circuitry.

Operation of the circuit 10 of FIG. 3 will now be described. In one embodiment, bias control circuits 142 and 140 of FIG. 3 serve a similar function as bias control circuitry 240 in FIG. 2. In FIG. 3, separate bias control circuits 142 and 140 are used to control the p-channel device 112 and the n-channel device 114, respectively.

In one embodiment, bias control circuits 142 receives one or more select signals 154 which are used by voltage select circuit 150 to provide a decoding type function and to determine the signal provided from voltage select circuit 150 to voltage adjust circuit 148. Note that this input to voltage adjust circuit 148 may be one or more analog signals, or may be one or more digital signals. Voltage adjust circuit 148 may be any type of circuit that adjust an output voltage level based on an input. For example, voltage adjust circuit 148 may be implemented using a level shifter, an amplifier, or any other desired and appropriate circuit. Voltage adjust circuit 148 then provides the pdrive signal 111 and pbias signal 122 to different gates of device 112.

In one embodiment, bias control circuits 140 receives one or more select signals 152 which are used by voltage select circuit 146 to provide a decoding type function and to determine the signal provided from voltage select circuit 146 to voltage adjust circuit 144. Note that this input to voltage adjust circuit 144 may be one or more analog signals, or may be one or more digital signals. Voltage adjust circuit 144 may be any type of circuit that adjust an output voltage level based on an input. For example, voltage adjust circuit 144 may be implemented using a level shifter, an amplifier, or any other desired and appropriate circuit. Voltage adjust circuit 144 then provides the ndrive signal 113 and nbias signal 124 to different gates of device 114.

Note that the bias control circuitry 140, 142 provides the bias signals (e.g. 122, 124) to the MGFETS 112, 114, respectively, and thus determines the voltage levels of the bias signals. The voltage levels of the bias signals then affect whether the MGFETs 112, 114 are conducting or non-conducting. In addition the voltage levels of the bias signals also affect the output impedance of the output driver 10. Note that in alternate embodiments, the voltage level of one or more of the bias signals may not be variable.

Note that one embodiment of circuit 138 of FIG. 3 may function in the same manner as described above for circuit 38 of FIG. 1. Thus, output driver circuit 10 may use bias control circuits 142 and 140 to determine a variable output impedance which is provided at output 130.

In an alternate embodiment, predriver stage 136, instead of the bias control circuitry 142, 140 may directly drive pdrive signal 111 and ndrive signal 113. In this case, bias control circuitry 142 and 140 may still be used to provide pbias signal 122 and nbias signal 124. This embodiment may potentially allow improved granularity of control over the output impedance of circuit 10, and/or may require less integrated circuit area to implement.

FIG. 4 illustrates, in partial block and partial schematic diagram form, an exemplary output driver circuit 300 having a plurality of MGFET devices 360, 362, 370, 372 in accordance with an alternate embodiment of the present invention. In the illustrated example, a predriver stage or circuit 336 is coupled to an output stage 338. In an alternate embodiment, bias control circuitry (e.g. as described above in FIGS. 2 and 3) may be interposed between the predriver stage 336 and the output buffer stage 338 in order to allow adjustment of the drive voltages and bias voltages provided to MGFET devices 360, 362, 370, 372. Although the embodiment illustrated in FIG. 4 shows two p-channel MGFET transistors 360, 362 and two n-channel MGFET transistors 370, 372, alternate embodiments may use any number of MGFET transistors. In one embodiment, predriver 336 receives an enable signal 328, receives an input signal 326, and receives a plurality of select signals 352 as inputs. In one embodiment, predriver 336 may be implemented in the same manner as predriver circuit 36 of FIG. 1. In alternate embodiments, predriver circuit 336 may be implemented using any desired circuitry.

Predriver 336 provides a drive signal 311 to a first control electrode or gate of p-channel MGFET 360 and provides a bias signal 322 to a second control electrode or gate of MGFET 360. Predriver 336 also provides a drive signal 421 to a first control electrode or gate of p-channel MGFET 362 and provides a bias signal 422 to a second control electrode or gate of MGFET 362. Similarly, predriver 336 provides a drive signal 313 to a first control electrode or gate of n-channel MGFET 370 and provides a bias signal 324 to a second control electrode or gate of MGFET 370. Predriver 336 also provides a drive signal 423 to a first control electrode or gate of p-channel MGFET 372 and provides a bias signal 424 to a second control electrode or gate of MGFET 372. Note that the two control electrodes of each MGFET 360, 362, 370, 372 may be independent of each other. In an alternate embodiment, the two control electrodes of each MGFET 360, 362, 370, 372 may be coupled to the same signal, and thus may not be independent of each other. Alternately, a first portion of the MGFETS in circuit 300 may have multiple gates coupled to the same signal (gates are not independent of each other), while a second portion of the MGFETS in circuit 300 may have multiple gates coupled to different signals (these multiple gates are independent of each other).

A first current electrode of each MGFET 360, 362 is coupled to a first power supply voltage 332 (e.g. power or VDD), and a second current electrode of each MGFET 360, 362 is coupled to a first terminal of a resistive element 320. A first current electrode of each MGFET 370, 372 is coupled to the first terminal of resistive element 320, and a second current electrode of each MGFET 370, 372 is coupled to a second power supply voltage 334 (e.g. approximately ground or VSS). A second terminal of resistive element 320 provides an output signal 330. Alternate embodiments may not use resistive element 320. Yet other embodiments may use any type of circuitry between the common current electrodes of MGFETs 360, 362, 370, 372 and the output signal 330.

In one embodiment, output signal 330 is provided external to the integrated circuit on which output driver circuit 300 is formed. This external provision of output signal 330 may be performed in any desired manner, including, for example, any type of integrated circuit terminal such as a pad, bump, and or pin. In the illustrated embodiment, the circuit 300 is an output buffer only with no input capability. However, in alternate embodiments, circuit 300 may be implemented as an input/output buffer which also has an input path (not shown) from the integrated circuit terminal. In one embodiment, as illustrated in FIG. 1, the input path may be via output 330. In alternate embodiments of circuit 300, predriver circuit 336 may not be present, or may be implemented using any desired circuitry. The drive signals 311, 421 and bias signals 313, 423 may be provided by any appropriate circuitry and in a desired manner as described below.

Operation of the circuit 300 of FIG. 4 will now be described. FIG. 4 illustrates one embodiment of a variable output impedance driver 300. The output impedance control is digitally controlled by adding more devices 360-362 and 370-372. Devices 360-362 and 370-372 can be selectively turned on or off by select signals 352 to achieve a desired output impedance at output 330. For example, enabling device 362 in addition to device 360 would lower the output impedance of output driver circuit 300. In addition, the impedance of each device (e.g. 360-362, 370-372) may be adjusted by digitally asserting one or both of the gate electrodes for that device. Note that the voltages applied to the multiple gate electrodes of devices 360-362, 370-372 are digital, and thus are approximately either VDD 332, or VSS 334. Note that in the illustrated embodiment, the p-channel devices 360-362 may be controlled independent of the n-channel devices 370-372. The enable signal 328 may be used to disable all devices 360-362, 370-372 if it is desired to tri-state circuit 300 (i.e. to place it in a high impedance state when output 330 is functioning to receive an input signal (e.g., see input circuitry 19 of FIG. 1).

FIG. 5 illustrates, in partial block and partial schematic diagram form, an exemplary output driver circuit 500 having a plurality of MGFET devices 560, 562, 570, 572 in accordance with an alternate embodiment of the present invention. In the illustrated example, a predriver stage or circuit 536 is coupled to an output stage 538 to provide drive signals (pdrive 511 and ndrive 513). In addition, bias generator circuitry 580 is coupled to output stage 538 to provide bias signals (pbias 522 and nbias 524). The predriver stage 536 allows adjustment of the drive voltages provided to MGFET devices 560 and 572, and the bias generator 580 allows adjustment of the bias voltages provided to MGFET devices 562 and 570. Although the embodiment illustrated in FIG. 5 shows two p-channel MGFET transistors 560, 562 and two n-channel MGFET transistors 570, 572, alternate embodiments may use any number of MGFET transistors.

In one embodiment, predriver 536 receives an enable signal 528 and receives an input signal 526. Bias generator circuit 580 receives one or more select signals 552 as inputs. In one embodiment, predriver 536 may be implemented in the same manner as predriver circuit 36 of FIG. 1. In alternate embodiments, predriver circuit 536 may be implemented using any desired circuitry.

Predriver 536 provides a drive signal 511 (pdrive) to both a first control electrode or gate and to a second control electrode or gate of p-channel MGFET 560. Bias generator 580 provides a bias signal 522 (pbias) to both a first control electrode or gate and to a second control electrode or gate of p-channel MGFET 562. Predriver 536 also provides a drive signal 513 (ndrive) to both a first control electrode or gate and to a second control electrode or gate of n-channel MGFET 572. Bias generator 580 provides a bias signal 524 (nbias) to both a first control electrode or gate and to a second control electrode or gate of n-channel MGFET 570. Note that in the illustrated embodiment, the two control electrodes of each MGFET 560, 562, 570, 572 are coupled to the same signal, and thus are not independent of each other. In alternate embodiments, the two control electrodes of each MGFET 560, 562, 570, 572 may be coupled to different signals, and thus may be independent of each other. Alternately, a first portion of the MGFETS in circuit 500 may have multiple gates coupled to the same signal (gates are not independent of each other), while a second portion of the MGFETS in circuit 300 may have multiple gates coupled to different signals (these multiple gates are independent of each other).

A first current electrode of MGFET 560 is coupled to a first power supply voltage 532 (e.g. power or VDD), and a second current electrode of MGFET 560 is coupled to a first current electrode of MGFET 562. A second current electrode of MGFET 562 is coupled to a first terminal of a resistive element 520 and to a first current electrode of MGFET 570. A second current electrode of MGFET 570 is coupled to a first current electrode of MGFET 572. A second current electrode of MGFET 572 is coupled to a second power supply voltage 534 (e.g. approximately ground or VSS). A second terminal of resistive element 520 provides an output signal 530. Alternate embodiments may not use resistive element 520. Yet other embodiments may use any type of circuitry between the common current electrodes of MGFETs 562 and 570 and the output signal 530.

In one embodiment, output signal 530 is provided external to the integrated circuit on which output driver circuit 500 is formed. This external provision of output signal 530 may be performed in any desired manner, including, for example, any type of integrated circuit terminal such as a pad, bump, and or pin. In the illustrated embodiment, the circuit 500 is an output buffer only with no input capability. However, in alternate embodiments, circuit 500 may be implemented as an input/output buffer which also has an input path (not shown) from the integrated circuit terminal. In one embodiment, as illustrated in FIG. 1, the input path may be via output 530. In alternate embodiments of circuit 500, predriver circuit 536 may not be present, or may be implemented using any desired circuitry. The drive signals 511, 513 and bias signals 522, 524 may be provided by any appropriate circuitry and in a desired manner as described below.

Operation of the circuit 500 of FIG. 5 will now be described. FIG. 5 illustrates one embodiment of a variable output impedance driver 500. In the illustrated embodiment, the output impedance control is analog controlled by signals pbias 522 and nbias 524 which are generated by bias generator circuitry 580. The analog voltages of pbias 522 and nbias 524 are determined by bias generator circuitry 580 using select signals 352 to select the desired voltages. Bias generator circuitry 580 may be implemented in any desired manner, including manners known in the art. Note that the MGFET devices 560 and 572 may be used as a digital switch to determine the voltage, and thus the logic state, of output 530. In the illustrated embodiment, MGFET devices 562 and 570 may be used to control the output impedance of output driver circuit 500. In addition, for some embodiments, the voltages of pbias 522 and nbias 524 may be chosen to appropriately protect devices 560 and 572 from high voltages on output node 530.

FIG. 6 is a partial isometric view of one embodiment of a multiple gate field effect transistor (MGFET) 610 that can be used with the circuits of FIGS. 1-5. The MGFET 610 includes a fin structure 612 formed over a substrate, for example a bulk substrate or silicon-on-insulator (SOI). The fin structure has first and second sidewalls. The fin structure 612 is formed from a semiconductor material. A dielectric layer 613 is formed over the surface of the substrate and the fin structure and a layer of gate material is formed over the dielectric layer 613 as illustrated in FIG. 6 to form gate electrodes on opposite sides of the fin structure 612. Specifically, the gate material is formed over the substrate, the first sidewall of the fin to form a first gate 618, and the second sidewall of the fin to form a second gate 620. The first and second gates 618 and 620 have a predetermined height on the sidewalls of the fin structure 612, and are electrically isolated from each other. In one embodiment, the gate material may be deposited over the top of the fin structure, and then selectively removed to provide isolation between the first and second gates 618 and 620. Fin structure 612 includes current terminal regions 614 and 616 located in each end of fin structure 612. In one embodiment where the resultant transistor structure is a field effect transistor (FET), current terminal regions 614 and 616 serve as the source and drain regions, respectively. Contacts 622, 624, 626, and 628 provide for electrical connection to the MGFET 10. The contacts connect to metal layers implemented above the gate and the source/drain terminals (not shown). Note that in the illustrated embodiment, one contact is shown for each gate structure and source/drain connections; however, there may be any number of contacts as long as an acceptable electrical connection can be made. A nitride layer 630 is formed over a top surface of the fin structure 612. In other embodiments, nitride layer 630 may be made of other materials (e.g. other dielectrics).

During the operation of MGFET 10, when a voltage is applied to one of the gates 618 and 620, a channel region is formed underneath the gate in the fin structure 612 providing a current path between the source and drain current terminal regions 614 and 616, respectively.

Note that the channel regions may be undoped, doped to be N-type semiconductor, P-type semiconductor, or a combination of N-type and P-type semiconductor.

The illustrated embodiment discloses a transistor structure having two independent gates. In other embodiments, a transistor structure may have more than two gate structures. For example, the MGFET 610 may have an additional gate on top of the fin structure 612 in place of the nitride layer 630. Also, in other embodiments, a plurality of transistors like MGFET 610 may be connected together in parallel if additional drive strength is required. Although the MGFET 610 illustrated in FIG. 6 has two independent gates capable of being coupled to different voltages, alternate embodiments of MGFET may have two or more physical gate structures that are electrically coupled so that the gate structures are at approximately the same voltage or potential. For example, if a MGFET device is hard-wired in a circuit so that the same signal is always provided to both gates of a MGFET device (e.g. MGFET 610), then the two gates of this MGFET device are no longer independent. However, if a MGFET device is hard-wired in a circuit so that it is possible to provide different signals having different voltages to each gate of a same MGFET device (e.g. MGFET 610), then the two gates of this MGFET device are independent.

Note that for the various MGFET devices illustrated in FIGS. 1-6, the thickness of each gate oxide may be varied from thin to thick depending upon how much voltage each MGFET device needs to handle (e.g. the difference in voltage between VSS and VDD for MGFETs 12 and 14 of FIG. 1). Note that various known circuit techniques may be used so that devices having thin gate oxide may be used with higher voltage differences.

In the foregoing specification, the invention has been described with reference to specific embodiments. However, one of ordinary skill in the art appreciates that various modifications and changes can be made without departing from the scope of the present invention as set forth in the claims below. For example, the optional resistive element in each figure may be implemented in any manner, such as, for example, using one or more active devices and/or one or more passive devices. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. An output driver circuit, comprising:
a first drive input for receiving a first drive signal;
a second drive input for receiving a second drive signal;
a first bias input for receiving a first bias signal;
a second bias input for receiving a second bias signal;
a first multiple gate transistor that provides a first gate coupled to the first drive input, that provides a second gate coupled to the first bias input, that provides a first current electrode coupled to a first power supply voltage, and that provides a second current electrode;
a second multiple gate transistor that provides a first gate coupled to the second drive input, that provides a second gate coupled to the second bias signal, that provides a first current electrode coupled to a second power supply voltage, and that provides a second current electrode coupled to the second current electrode of the first MGFET; and
an output coupled to the second current electrode of the first MGFET and coupled to the second current electrode of the second MGFET.

2. A circuit as in claim 1, wherein the first drive input and the first bias input are electrically coupled to each other, and wherein the second drive input and the second bias input are electrically coupled to each other.

3. A circuit as in claim 1, wherein the first bias signal is used to control an output impedance of the output driver circuit.

4. A circuit as in claim 3, wherein the second bias signal is also used to control the output impedance of the output driver circuit.

5. A circuit as in claim 1, further comprising:
a resistive element coupled to the output.

6. A circuit as in claim 1, further comprising:
bias control circuitry for providing the first bias signal to the first bias input, and for providing the second bias signal to the second bias input.

7. A circuit as in claim 6, further comprising:
a predriver stage coupled to the bias control circuitry.

8. A circuit as in claim 1, further comprising:
a predriver stage coupled to the first drive input for providing the first drive signal, and coupled to the second drive input for providing the second drive signal.

9. A circuit as in claim 1, wherein the first gate and the second gate of the first multiple gate transistor are electrically independent of each other, and wherein the first gate and the second gate of the second multiple gate transistor are electrically independent of each other.

10. A circuit as in claim 1, further comprising:
bias control circuitry for providing the first bias signal to the first bias input, wherein the bias control circuitry determines a voltage level of the first bias signal, and wherein the voltage level of the first bias signal affects whether the MGFET is conducting or non-conducting, and wherein the voltage level of the first bias signal affects an output impedance of the output driver.

11. An output driver circuit, comprising:
a first multiple gate transistor having a first gate coupled to receive a first input signal, having a second gate coupled to receive a second input signal, having a first current electrode coupled to a first power supply voltage, and having a second current electrode;
a second multiple gate transistor coupled in parallel with the first multiple gate transistor, the second multiple gate transistor having a first gate coupled to receive a third input signal, having a second gate coupled to receive a fourth input signal, having a first current electrode coupled to the first power supply voltage, and having a second current electrode coupled to the second current electrode of the first multiple gate transistor;
a third multiple gate transistor having a first gate coupled to receive a fifth input signal, having a second gate coupled to receive a sixth input signal, having a first current electrode coupled to a second power supply voltage, and having a second current electrode coupled to the second current electrode of the first multiple gate transistor;
a fourth multiple gate transistor coupled in parallel with the third multiple gate transistor, the fourth multiple gate transistor having a first gate coupled to receive a seventh input signal, having a second gate coupled to receive an eighth input signal, having a first current electrode coupled to the second power supply voltage, and having a second current electrode coupled to the second current electrode of the first multiple gate transistor; and
an output coupled to the second current electrode of the first multiple gate transistor,
wherein at least one of the first, second, third, fourth, fifth, sixth, seventh, and eighth input signals is selectively varied in order to vary impedance at the output of the output driver circuit.

12. A circuit as in claim 11, further comprising:
a predriver stage coupled to the first, second, third, and fourth multiple gate transistors for providing the first, second, third, fourth, fifth, sixth, seventh, and eighth input signals.

13. A circuit as in claim 11, wherein the first gate and the second gate of the first multiple gate transistor are electrically independent of each other, and wherein the first gate and the second gate of the third multiple gate transistor are electrically independent of each other.

14. A circuit as in claim 13, wherein the first gate and the second gate of the second multiple gate transistor are electrically independent of each other, and wherein the first gate and the second gate of the fourth multiple gate transistor are electrically independent of each other.

15. A circuit as in claim 11, wherein the first and second multiple gate transistors are p-type, and the third and fourth multiple gate transistors are n-type.

16. An output driver circuit, comprising:
a first multiple gate transistor having a first gate coupled to receive a first input signal, having a second gate coupled to receive a second input signal, having a first current electrode coupled to a first power supply voltage, and having a second current electrode;
a second multiple gate transistor having a first gate coupled to receive a third input signal, having a second gate coupled to receive a fourth input signal, having a first current electrode coupled to the second current electrode of the first multiple gate transistor, and having a second current electrode;
a third multiple gate transistor having a first gate coupled to receive a fifth input signal, having a second gate coupled to receive a sixth input signal, having a first current electrode coupled to the second current electrode of the second multiple gate transistor, and having a second current electrode;
a fourth multiple gate transistor having a first gate coupled to receive a seventh input signal, having a second gate coupled to receive an eighth input signal, having a first current electrode coupled to the second current electrode of the third multiple gate transistor, and having a second current electrode coupled to a second power supply voltage; and
an output coupled to the second current electrode of the second multiple gate transistor,
wherein at least one of the first, second, third, fourth, fifth, sixth, seventh, and eighth input signals is selectively varied in order to vary impedance at the output of the output driver circuit.

17. A circuit as in claim 16, further comprising:
a predriver stage for providing the first, second, seventh, and eighth input signals.

18. A circuit as in claim 17, further comprising:
a bias generator for providing the third, fourth, fifth, and sixth input signals.

19. A circuit as in claim 11, wherein the first gate and the second gate of the first multiple gate transistor are electrically connected to each other.

20. A circuit as in claim 13, wherein the first gate and the second gate of the second multiple gate transistor are electrically connected to each other, wherein the first gate and the second gate of the third multiple gate transistor are electrically connected to each other, and wherein the first gate and the second gate of the fourth multiple gate transistor are electrically connected to each other.
